(19) United States
(12) Patent Application Publication
(10) Pub. No.: US 2019/0253053 A1
(43) Pub. Date: Aug. 15, 2019

(54) Pressure Sensing Display Device

(71) Applicant: Cambridge Touch Technologies Ltd., Cambridge (GB)

(72) Inventors: Arokia Nathan, Cambridge (GB); Jackson Chi-Sun Lai, Markham (CA); Suk-Bae Cha, Tokyo (JP); Corbin Church, Westmount (CA)

(21) Appl. No.: 16/390,094

(22) Filed: Apr. 22, 2019

Related U.S. Application Data
(63) Continuation of application No. 15/669,941, filed on Aug. 6, 2017.
Application No. 15/669,941 is a continuation of application No. 13/935,392, filed on Jul. 3, 2013, now abandoned.
(60) Provisional application No. 61/668,439, filed on Jul. 5, 2012.

(51) Int. Cl. H03K 17/96; G06F 3/044; G06F 3/041

(52) U.S. Cl. CPC H03K 17/962; G06F 3/044; H03K 17/9625; G06F 2203/04106; G06F 3/0416; G06F 3/0414; G06F 3/0412

(57) ABSTRACT

Integrated touch displays with combined pressure and projected capacitance touch capabilities are provided. A sensing electrode layer and, optionally, a driving electrode layer, has a plurality of discrete pads deposited, patterned, printed or laminated on a cover lens or color filter substrate. Each of the discrete pads may be formed of an optically transparent conductor.

This application is a continuation of U.S. patent application Ser. No. 15/669,941, filed Aug. 6, 2017, which application is a continuation of U.S. patent application Ser. No. 13/935,392, which was filed on Jul. 3, 2013, and claims priority from U.S. provisional application No. 61/668,439, filed Jul. 5, 2012, all of which are incorporated by reference as if fully disclosed herein.

### FIELD

The described embodiments relate to touch sensing digital displays and, in particular, to force or pressure sensing in touch sensing displays.

### BACKGROUND

Touch panel displays are widely used in consumer electronics, such as smartphones and computing tablets, among other devices. Broadly speaking, there are two types of touch panel technologies currently used in consumer electronics: projected capacitance and resistive. Both types of touch panels typically can only sense the location and time of a touch event on the touch panel (e.g., from a finger or stylus). The location of a touch event is typically recorded only in two dimensions (e.g., x-y coordinates). Conventional touch panels are unable to sense in a third dimension to determine the magnitude of a touch force (e.g., a z-coordinate). Prior attempts at three-dimensional sensing have typically focused on the inclusion of a sensitive analog element. Conventionally, the inclusion of an analog element in what is otherwise a digital system has been costly, bulky and non-trivial.

### SUMMARY

In a first broad aspect, there is provided a projected capacitance touchscreen device comprising a pressure sensing assembly, the pressure sensing assembly comprising: a driving electrode layer; a sensing electrode layer; and a pressure sensing layer provided between the driving electrode layer and the sensing electrode layer, wherein the pressure sensing layer acts as a dielectric.

The driving electrode layer may comprise a biasing layer.

The driving electrode layer may comprise a plurality of conductive traces, and each trace may comprise one or more driving pads.

Each driving pad may be formed of an optically transparent conductive material.

The sensing electrode layer may comprise a plurality of conductive traces, and each trace may comprise one or more sensing pads.

The sensing pad may be formed of an optically transparent conductive material.

The driving pads may be aligned with the sensing pads.

The sensing or driving pads may be shaped to maximize fringing fields and a change in capacitance between the sensing electrode layer and the driving electrode layer in response to stimulus. The sensing or driving pads may have a polygonal shape.

Each conductive trace of the driving electrode layer may terminate in one driving pad.

Each conductive trace of the sensing electrode layer may terminate in one sensing pad.

The conductive trace may further comprise an external portion at a periphery of the device, wherein the external portion is formed of an optically opaque conductive material.

Each conductive trace of the driving electrode layer may comprise a plurality of driving pads.

Each conductive trace of the sensing electrode layer may comprise a plurality of sensing pads.

The device may further comprise a detection circuit operatively connected to the plurality of conductive traces of the sensing layer. The detection circuit may be selectively operable in a first mode and a second mode, wherein in the first mode the detection circuit is configured to detect a change in capacitance at one or more of the conductive traces of the sensing layer, and wherein in the second mode the detection circuit is configured to detect a change in electric current at one or more of the conductive traces of the sensing layer.

The device may further comprise a processor, wherein the processor is configured to interpret pressure data from the one or more sensing pads as an image map. The pressure data may be interpreted using correlated double sampling, compressive sensing, or both.

The pressure data may comprise a plurality of pressure levels, and each pixel in the image map may have a respective pressure level mapped as a level of grey.

### BRIEF DESCRIPTION OF THE DRAWINGS

The detailed description will be better understood in conjunction with the accompanying drawings as follows:

FIG. 1A is a simplified plan view of a display subassembly.

FIG. 1B is a simplified plan view of an example cover assembly.

FIG. 2 is a simplified cross-sectional view of a portion of an example display assembly.

FIG. 3 is a simplified cross-sectional view of another example display assembly.

FIG. 4 is a plan view of an example pad layout for the display assembly of FIG. 3.

FIG. 5 is a simplified schematic diagram of an example sensor for combined projected capacitive and pressure sensing.

FIG. 6 is a schematic diagram of an example pressure sensing circuit.

FIG. 7 is a cover assembly with an example pad and trace geometry.

FIG. 8 is a cover assembly with another example pad and trace geometry.

FIG. 9 is a simplified schematic of an example touch event signal flow.

The present embodiments are detailed below with reference to the listed Figures.

### DETAILED DESCRIPTION OF THE EMBODIMENTS

Before explaining the present apparatus in detail, it is to be understood that the apparatus is not limited to the particular embodiments and that it can be practiced or carried out in various ways.

The described embodiments relate to touch sensing digital displays and, in particular, to force or pressure sensing in touch sensing displays.

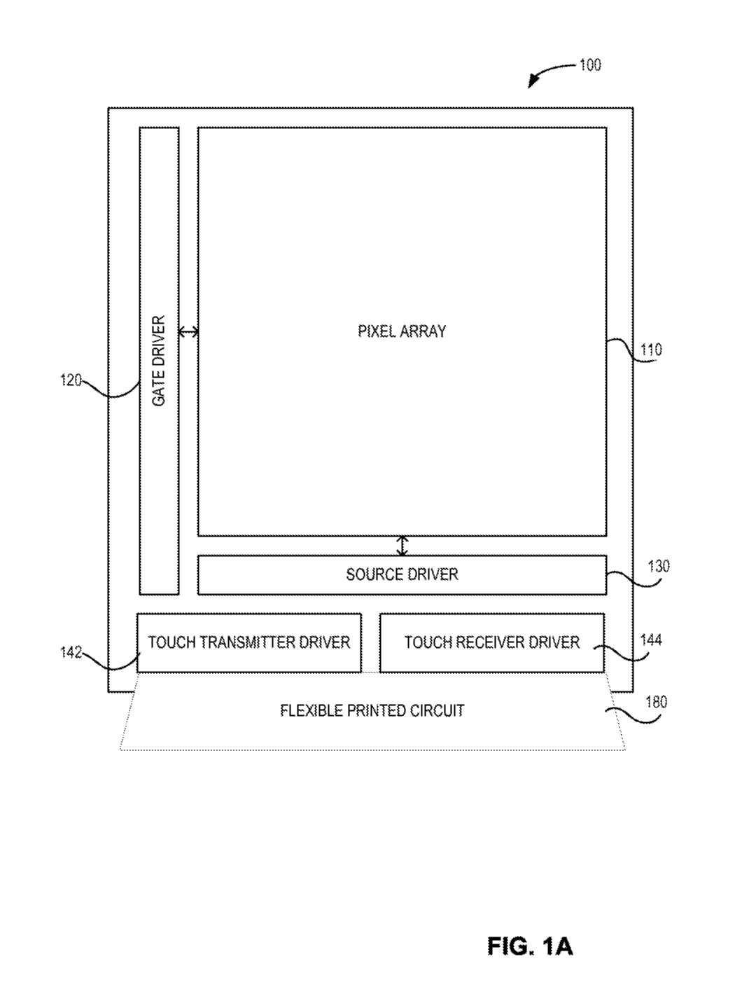

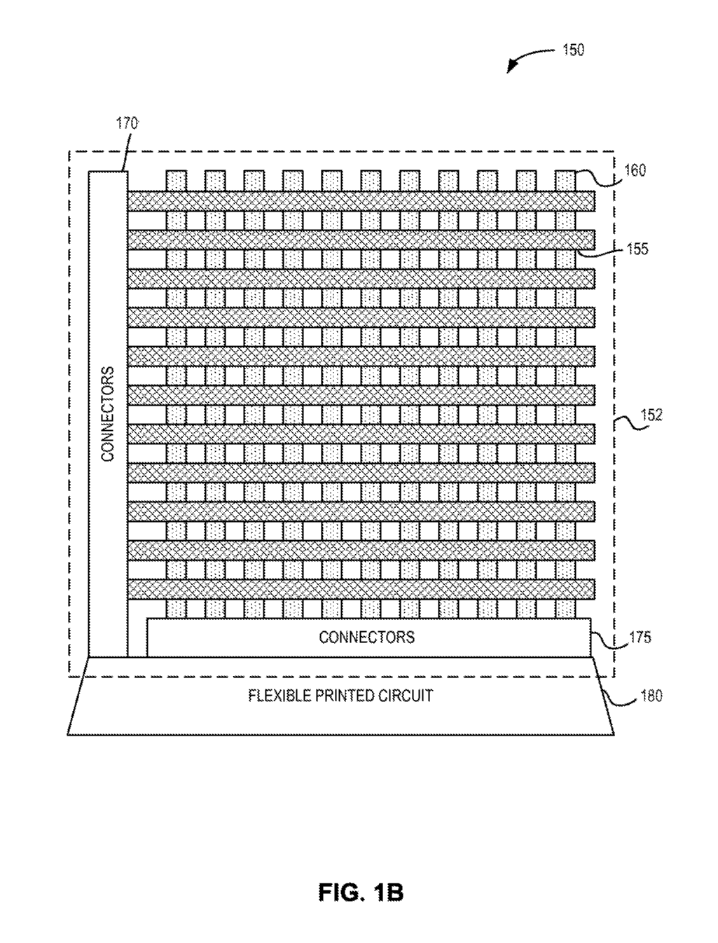

Turning to the Figures. FIG. 1A is a simplified plan view of a display subassembly such as that used in a touch sensitive display. Display subassembly 100 includes a pixel array 110, a gate driver 120 and a source driver 130.

Pixel army 110 can include a backplane with an active matrix comprising individually addressable pixels (e.g., liquid crystal display (LCD) or light emitting diode (LED) elements), and a front plane for optical modulation (e.g., color filters, polarizers, etc.). The backplane can include a plurality of layers, formed of various materials such as glass, polyester and paper.

Each addressable pixel can comprise one or more transistors and, in particular, a thin-film transistor (TFT), for controlling the operation of the pixel. In some embodiments, each pixel can consist of separate sub-pixels, each individually controllable, that are provided with different color filters.

Gate driver 120 and source driver 130 are generally integrated circuits that drive the operation of pixel array 110. Both gate driver 120 and source driver 130 can be integrated into pixel array 110, or provided as separate circuits in a display module using, for example, a flexible printed circuit, chip on glass or chip on flex approach.

In operation, display subassembly 100 forms an image by scanning lines of pixels in pixel array 110. Gate driver 120 provides a signal to open or activate selected pixels (or sub-pixels) in each line of pixel array 110. Source driver 130 then charges each pixel in the line to a preconfigured voltage.

FIG. 1B is a simplified plan view of an example cover assembly with integrated touch traces, such as that used in a touch sensitive display.

Cover assembly 150 generally includes multiple layers can be fabricated by lamination or equivalent methods. In some embodiments, an air gap between layers can be acceptable. An outer layer 152 can be glass or plastic, and is generally the layer that a user may contact with a finger or stylus. A first layer of transmitter touch traces, such as horizontal traces 155, can be provided on the underside of the outer layer. The traces can be formed by depositing a suitable conductor on the glass substrate. For example, indium tin oxide (ITO) or indium zinc oxide (IZO) can be used, as they are substantially optically transparent and can be overlaid on a display pixel array, such as array 110 of FIG. 1A.

An intermediate dielectric or insulating layer (e.g., glass) can be provided, and a second layer of receiver touch traces, such as vertical traces 160, can be provided in similar fashion to form a projected capacitance (pro-cap) sensing grid.

In the illustrated example, each of the horizontal traces 155 is electrically coupled via a plurality of connectors 170 and a flexible printed circuit 180 to a transmitter driver circuit, such as touch transmitter driver 142 of FIG. 1A, located off-assembly. Similarly, each of the vertical traces 160 is electrically coupled via connectors 175 and the flexible printed circuit 180 to a receiver driver circuit, such as touch receiver driver 144 of FIG. 1A. So as not to obscure the illustration, each of the respective conductive paths is not individually illustrated, however each horizontal and vertical trace can be individually and uniquely coupled to a respective input or output of the respective driver circuit.

The connectors 170 and 175 can be formed of ITO or IZO, or can be formed of opaque materials that exhibit lower resistance, thus allowing for more compact arrangement (e.g., at the periphery of a display).

In one or more embodiments, the connectors can be conductors.

In operation, the touch transmitter driver 142 applies a voltage to the transmitter traces 160 to create an electrostatic field. In the absence of an external stimulus (e.g., finger or stylus), the electrostatic field has a regular pattern across the grid. Each intersection of a transmitter and receiver trace forms a capacitor, which has a corresponding capacitance that can be measured by a receiver circuit.

When a conductive object contacts the panel, the electrostatic field becomes locally distorted. This distortion causes a change in capacitance (e.g., reduction in mutual capacitance) at an intersection of the transmitter and receiver traces. This change in capacitance can be determined by measuring a voltage on each of the receiver traces, to identify the location of a touch event on the grid.

For a typical screen of between 4 and 5 diagonal inches, there are from 10 to 16 transmitter traces 160, and from 10 to 16 receiver traces 155, resulting from 100 to 256 distinct touch locations. Traces are typically from 4 mm to 6 mm in width, to capture a typical finger touch.

In the illustrated example, the image and touch driver circuits are shown as being integrated on the display panel, however in other embodiments, one or more driver circuits may be provided on a separate assembly, and connected via a flexible printed circuit or other suitable connector.

Provision of touch traces 155 and 160 in the cover assembly facilitates larger signal swings, which increase signal-to-noise ratio, due to the proximity of the finger or stylus to the traces.

In addition, by providing only touch traces on the cover assembly, the ease of repair or replacement is increased, while minimizing cost of repair, since the driving circuits are located on another module.

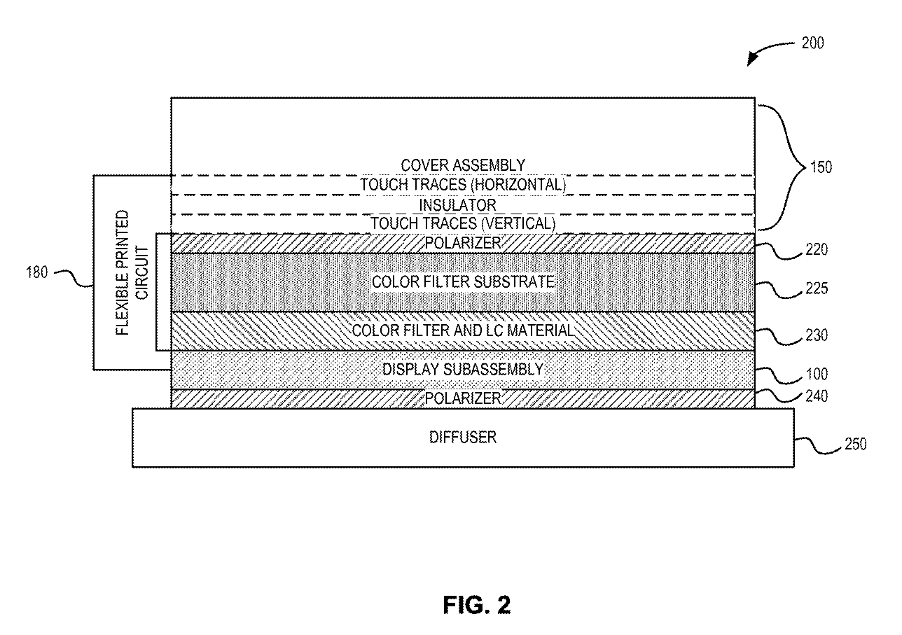

FIG. 2 is a simplified cross-sectional view of a portion of an example display assembly 200. The display assembly includes the display subassembly 100 of FIG. 1A and the cover assembly 150 of FIG. 1B, along with the flexible printed circuit 180 connecting touch traces to respective driver circuits.

In particular, the display assembly 200 has a diffuser 250 that serves as a base layer (e.g., bottom layer or substrate). The diffuser 250 can be a light guide plate (LGP), a brightness enhancing film (BEF) or other suitable diffusing element that serves to diffuse light from, for example, an LED backlight that produces broad spectrum (e.g., white) light.

A polarizer 240 is stacked atop the diffuser 250 to polarize light from the diffuser 250 and direct it through the display subassembly 100. The display subassembly 100 is a TFT layer that includes integrated circuits for controlling each pixel or sub-pixel element in the display assembly 200.

A color filter and liquid crystal layer (LC Material) 230 is stacked atop the display subassembly 100. The color filter and liquid crystal layer 230 includes liquid crystal elements that respond to control outputs from the display subassembly 100 to become selectively opaque or partially opaque. Color filter elements are used to admit only selected wavelengths to cause the pixels or sub-pixels to appear to provide only light of the desired color (e.g., red, green, blue).

A color filter substrate 225 is stacked atop the layer 230. The color filter substrate 225 can be a glass substrate, for example, upon which the layer 230 is adhered or affixed. Generally, the liquid crystal portion of layer 230 is below the color filter portion. An additional polarizer 220 can be provided to ensure that stray light does not escape.

The cover assembly 150 as described herein can be stacked atop the polarizer 220. As described, the horizontal and vertical touch traces of the cover assembly 150 can be coupled to respective driver circuits in the display subassembly 100.

Each of the layers of display assembly 200 can be fixed to the other, for example by lamination using a resin or other optically clear adhesive (OCA), portions of the assembly can also be sealed together during fabrication.

Current conventional touch screen displays generally employ pro-cap technology such as that described in FIGS. 1A, 1B, and 2. However, currently there is no practical pro-cap technology that incorporates pressure sensing capability. In addition, current methods of pro-cap device construction and driving result in noisy signals that may result in degraded touch performance.

The described embodiments generally provide integrated touch displays with combined pressure and projected capacitance touch capabilities, and methods of fabricating the same. The described embodiments are generally built in a hybrid construction that results in low noise, low latency, low power and low cost. At least some embodiments provide a “one glass solution” (OGS) or “on-cell” construction, on a variety of substrate types (e.g., glass, film, or laminates thereof).

In general, the described embodiments combine all the conventional attributes of pro-cap technology with the additional capability of sensing force or pressure applied to a planar surface, where both the magnitude and location of the force are measured. In addition, the described embodiments may facilitate increased signal-to-noise ratio in the detection of pro-cap touch events and force, while also allowing for reduced latency effects.

The described embodiments are suitable for use in touch panels, including high resolution touch panels such as those found in mobile computing devices (e.g., smartphones, tablets), personal computers, industrial devices and the like.

Pressure sensing can be implemented in capacitive touch sensing devices by incorporating a layer of pressure sensing material in the display stack. This pressure sensing material may be a material that exhibits a piezoelectric or quantum tunneling effect. That is, the pressure sensing material exhibits a change in one or more electrical property (e.g., voltage) corresponding to an applied force or pressure that deforms the material. For example, an applied force may induce a voltage across a piezoelectric material, which results in a current flowing between two terminals connected to the material.

In the case of piezoelectric materials, this change in electrical property may be measured across a portion of the material using two leads or terminals.

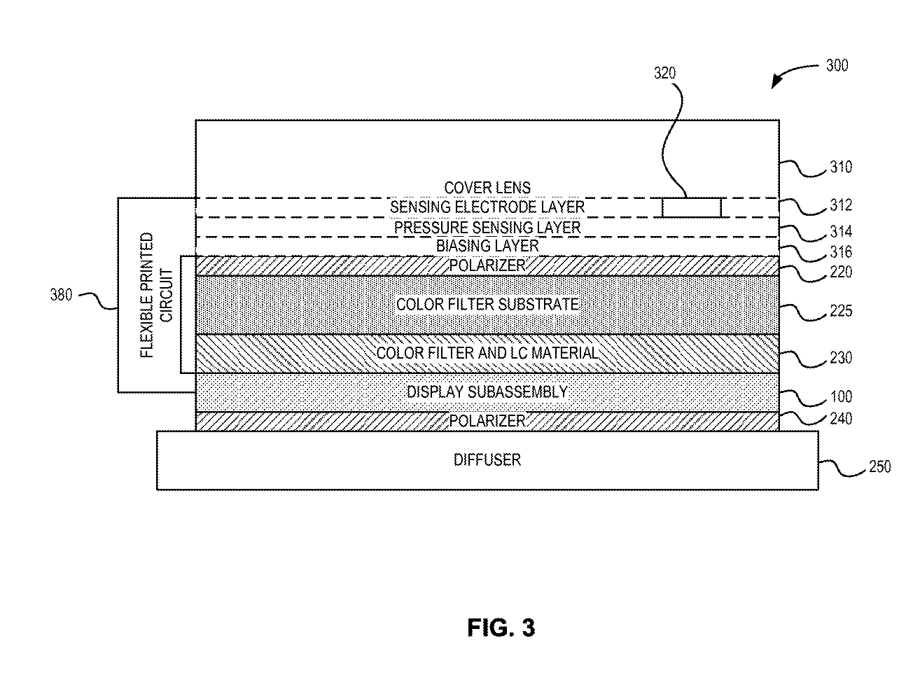

FIG. 3 is a simplified cross-sectional view of a portion of an example display assembly 300, which incorporates a pressure sensing layer. The display assembly 300 contains layers generally analogous to those of display assembly 200 of FIG. 2, which is labeled with like reference numerals.

In contrast to the display assembly 200, the example display assembly 300 comprises a cover lens 310, a sensing electrode layer 312, a pressure sensing layer 314 and a biasing layer 316. The flexible printed circuit 380 is operatively connected to each of layers 312, 314 and 316, as well as display subassembly 100.

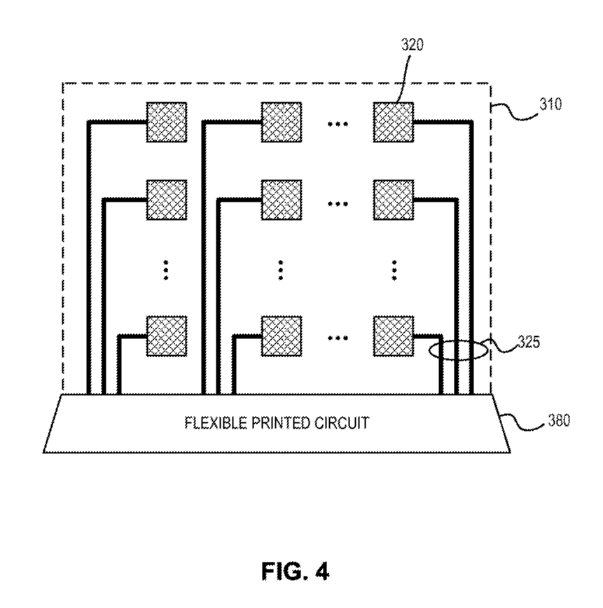

Sensing electrode layer 312 has a plurality of discrete pads 320 deposited, patterned, printed or laminated on the cover lens 310. Only one pad 320 is illustrated in FIG. 3, so as not to obscure the illustration. Each of the e pads can be formed of ITO, IZO or another suitable optically transparent conductor. Further detail regarding the layout of the sensing electrode layer 312 is provided with reference to FIG. 4.

Pressure sensing layer 314 is formed of a pressure sensing material, such as a piezoelectric material. The pressure sensing material also acts as a dielectric or insulating layer between sensing electrode layer 312 and biasing layer 316.

In some embodiments, the biasing layer 316 can act as a single large driving electrode, which works in conjunction with each of the pads 320 in the sensing electrode layer 312 to bias the pressure sensing material to facilitate pressure or force detection. Accordingly, when a force or pressure is applied to a portion of the assembly, one or more pads 320 in the vicinity of the applied force will register a change in voltage or current that will not be registered by the other discrete pads 320 outside the vicinity of the applied force.

The biasing layer 316 can be formed of an optically transparent conductor such as ITO or IZO. In some embodiments, the biasing layer 316 can be a substantially uniform “blanket” layer (i.e., not patterned).

In some embodiments, the pad and trace layer may be deposited on another layer of the display stack (e.g., color filter substrate 225), in which case pressure sensing layer 314 and biasing layer 316 can also be rearranged accordingly.

FIG. 4 is a plan view of one example pad layout for the example display assembly 300 of FIG. 3.

A plurality of pads 320 are shown arranged on the cover lens 310 in a grid fashion. Although only nine pads are shown, it will be understood that a larger number of pods can be used. The number of individual pads can be selected to provide high resolution spatial detection, for example at the sub-millimeter level.

Each pad 320 has a corresponding conductive trace 325, which is operatively connected to the flexible printed circuit 380, which connects to an external driver provided, for example on the display subassembly 100, shown in previous Figures. This allows the pads and traces to be implemented with existing cover lens or color filter manufacturing workflows.

The traces 325 can be formed of an optically transparent conductor such as ITO or IZO. The traces 325 can be routed in a regularized or repeating pattern, to facilitate placement of the pads 320 in a desired array pattern. In some cases, traces at the periphery of the display can be formed of an optically opaque conductor that exhibits lower resistance. As the traces do not switch at high frequency and need not switch simultaneously in pro-cap sensing, and further because the traces—being thin relative to the pads—occupy considerably less area than the pads, the effect of noise from the conductive traces is negligible.

The use of the pads 320 with the biasing layer 316 enables two forms of projected capacitive touch detection: mutual capacitance with two ITO layers: and self-capacitance with only the top patterned ITO layer.

In contrast to conventional pro-cap devices, which drive transmitter and receiver traces sequentially, monitoring of each of the pads 320 can be simultaneous, meaning there is no requirement for separate transmit and receive acts. Touch event detection can be synchronized with display programming to minimize or avoid signal interference from switching display pixels. Moreover, pads can be sensed multiple times within a display frame period to improve detection signal-to-noise ratio. This is contrary to conventional touch panel displays, where touch event detection is typically not synchronized to display functions.

In some embodiments, pressure sensing may be triggered in response to a capacitive touch detection, allowing for similar power consumption as with conventional capacitive touch sensing devices.

In some alternate embodiments. TFT amplification circuits can be printed or provided within each pad 320, allowing for in situ amplification rather than amplification in display subassembly 100. This approach may involve TFT processing of the cover lens or color filter, for example, but can significantly improve signal-to-noise ratio, as the detected signal charge can be amplified without any signal deterioration resulting from RC propagation along conductive traces 325.

TFTs can be more opaque than TO traces or pads, and thus can be aligned to the display's black matrix (BM) to minimize the impact on light transmittance. The BM is typically located on the color filter glass and may be marked with alignment marks, which can be used to align TFT amplification circuits to minimize visual artifacts.

In still further alternate embodiments, TFT amplification circuits can be printed or provided along a periphery of the cover lens or color filter, which typically is obscured by an opaque bezel, thus reducing or eliminating the requirement for alignment with the display BM. Short conductive traces can be provided between each pad 320 and the amplification circuits. This approach represents a reduction in signal-to-noise ratio (SNR) relative to in situ amplification, while still providing a modest gain in SNR relative to off-layer amplification.

Although TFT has been used as an example of a technology suitable for on-glass amplification circuits, other technologies such as amorphous silicon (a-Si), low temperature polysilicon (LTPS), metal oxide TFT (IGZO, MOx), organic TFTs, and the like can also be used.

In some embodiments, pads 320 and conductive traces 325 can be leveraged to perform both conventional pro-cap sensing of touch events and pressure sensing.

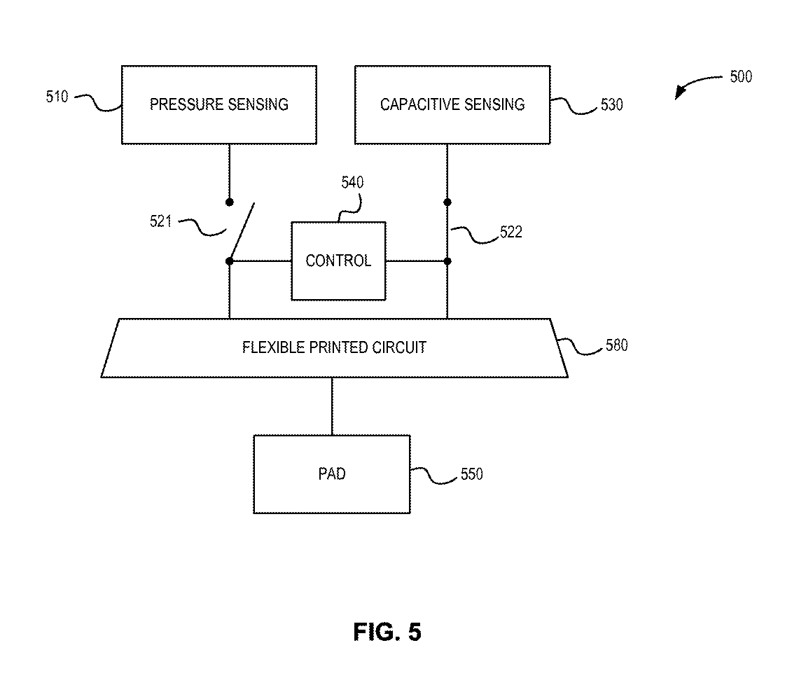

FIG. 5 is a simplified schematic diagram of an example sensor 500 for combined pro-cap and pressure sensing.

A pad 550, such as a pad 320 in previous Figures, can be connected (e.g., via a conductive trace 325 and a flexible printed circuit 580), to a pressure sensing circuit 510 and a capacitive sensing circuit 530. Although only one pad and one of each type of sensing circuit is illustrated in FIG. 5, in practice each individual pad 550 will have a corresponding pressure sensing circuit 510 and a corresponding capacitive sensing circuit 530, allowing all pads to be monitored simultaneously.

A control circuit 540 can selectively enable and disable switches 521 and 522, such that only one of the pressure sensing circuit 510 and the capacitive sensing circuit 530 is operatively coupled to the pad 550 at any one time. In some embodiments, a single control circuit 540 can regulate a plurality of switches for a plurality of pads 550.

Control circuit 540 can synchronize the readout and sensing of touch events to the display frame blanking period, for example, to further enhance SNR.

Capacitive sensing circuit 530 is generally a conventional pro-cap detection and amplification circuit.

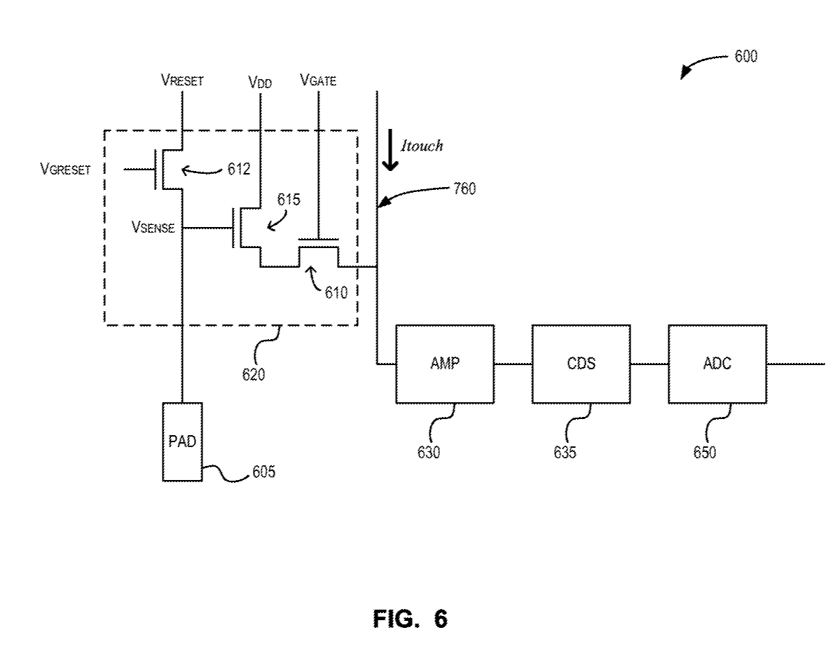

FIG. 6 is a schematic diagram of an example pressure sensing circuit 600 usable for the pressure sensing circuit 510.

Example pressure sensing circuit 600 is operatively coupled to a pad 605, and has a reset transistor 612, an integrating transistor 615 and an addressing transistor 610. Each transistor 612, 615 and 610 can be a PMOS or NMOS transistor, for example, depending on the specific circuit configuration.

In operation, an output of pad 605 is connected to a gate of a transistor, which serves as an integrator. In the example shown, a source of transistor is connected to a bulk supply voltage, causing a drain terminal of transistor to integrate the input to the gate of the integrating transistor 615. This integrated output can be coupled to a detection line 760 when the addressing transistor 610 is switched on.

The integrated output can be provided to a column amplifier 630, correlated double sampler 635, and digitized using an analog to digital convertor (ADC) 650.

The correlated double sampler 635 can be used to improve signal accuracy and signal-to-noise ratio. Generally, correlated double sampling is a technique used when measuring sensor outputs, which allows an undesired offset to be removed from a measured value (e.g., voltage, current). To perform correlated double sampling, the output of a sensor may be measured twice: once in a known condition and again in an unknown condition. The value measured during the known condition can be subtracted from the value measured during the unknown condition.

Correlated double sampling is used, for example, in switched capacitor op-amps to improve the gain of a charge-sharing amplifier, while adding an extra phase.

In the described embodiments, correlated double sampling can be performed by measuring the output of a pad after a reset is performed (e.g., the known condition) and subtracting this output from the output at the end of an integration period (e.g., the unknown condition). The reset may be performed, for example, by triggering the reset transistor 612.

In some embodiments, the correlated double sampler 635 can be omitted.

The example pressure sensing circuit 600 does not require that a pad provide an output voltage concurrently with the detection and amplification. Accordingly, a user's touch may occur separately from the detection event.

The reset transistor 612 can be activated to reset the output pad 605 to a default voltage (e.g., Vreset). This reset pulse can also act to erase any material memory effect that may exist in the pressure sensing element, which could affect the measurement calibration.

In some embodiments, an alternate geometry for the pads and traces can be used.

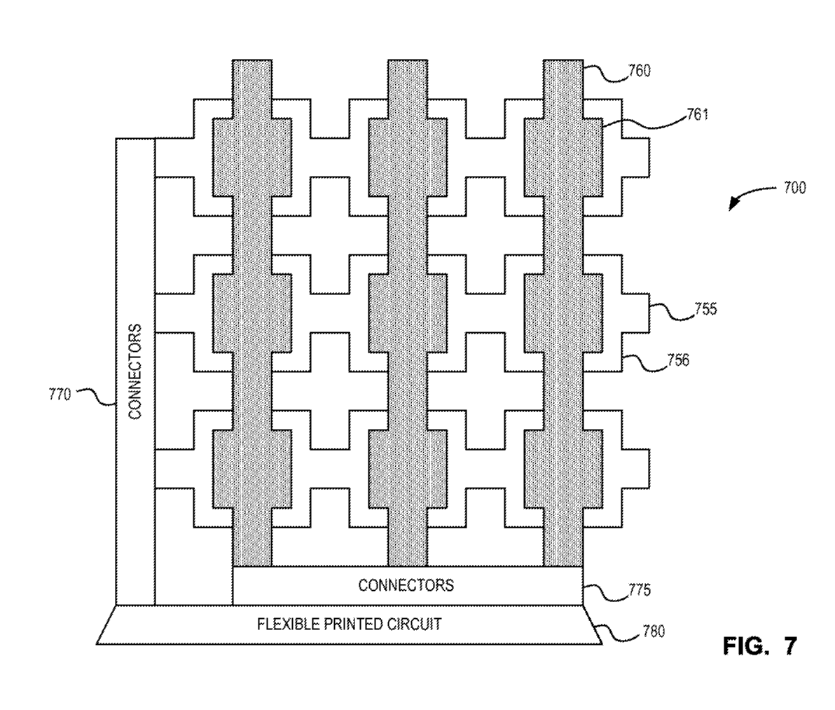

FIG. 7 is an example cover assembly with example pad and trace geometry, which can be used for both pro-cap and pressure sensing as described herein.

The cover assembly 700 is generally analogous to cover assembly 150, however each vertical trace 760 can have one or more integrated sensing pads 761, and is connected to a flexible printed circuit 780 via connectors 775.

Similarly, each horizontal trace 755 can have one or more integrated driving pads 756, and is connected to the flexible printed circuit 780 via connectors 770.

The use of enlarged, integrated pads both for driving and sensing can improve touch sensitivity with little or no change in the capacitance induced by an intermediate pressure sensing layer.

In general, it is desirable to increase the change in capacitance between the driving and sensing electrodes (or layers) that occurs in response to a touch. This change in capacitance can be increased by maximizing fringing fields. Electrode shapes can be selected to maximize fringing fields. In some cases, electrode shapes may result in a lower absolute capacitance, but a larger change in capacitance relative to some baseline shape.

Accordingly, the shapes of each integrated sensing pad and each integrated driving pad can be selected to increase and maximize the fringe capacitance (fringing field) between the driving and sensing electrodes (or between the sensing electrode and biasing layer).

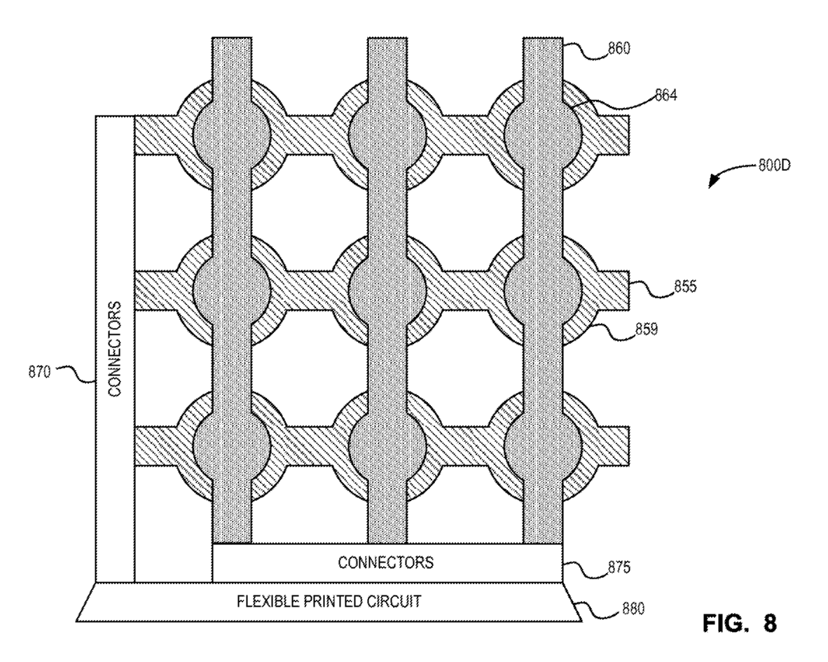

FIG. 8 is another cover assembly with example pad and trace geometry. The modified pad geometries can serve to increase the number of fringing fields, improving capacitive touch detection.

The cover assembly 800D is generally analogous to cover assembly 700. A plurality of horizontal traces 855 each have one or more integrated driving pads 859, and are connected to a flexible printed circuit 880 via connectors 870. A plurality of vertical traces 860 each have one or more integrated sensing pads 864, and are connected to the flexible printed circuit 880 via connectors 875. Each integrated driving pad 859 can have a diameter of approximately 5 mm, for example, and each integrated sensing pad sized accordingly.

As shown in FIG. 8, each integrated sensing pad 864 has a rounded shape, as illustrated. Likewise, each integrated driving pad 859 also has a rounded shape. However, various other shapes and configurations for the pads can also be used. For example, the driving and sensing pads can have polygonal shapes with a number of sides, such as from 3 to 8 sides, for example. In general, those shapes that maximize fringe capacitance between the sensing and driving electrodes may be preferred.

Although the described embodiments have been described primarily with reference to “one-glass solution” display technologies, the described techniques are applicable to many other display assembly structures, including “in-cell”, “on-cell”, and laminated panel approaches. In general, the described embodiments provide analog pressure sensing combined with conventional digital touch methods, such as projected capacitive sensing. The described embodiments also allow for high signal to noise ratio, enabling accurate, fast and sensitive touch and force sensing as well as ultra-low power modes that significantly improve battery life and device operation times compared to known touch panel architectures and technologies.

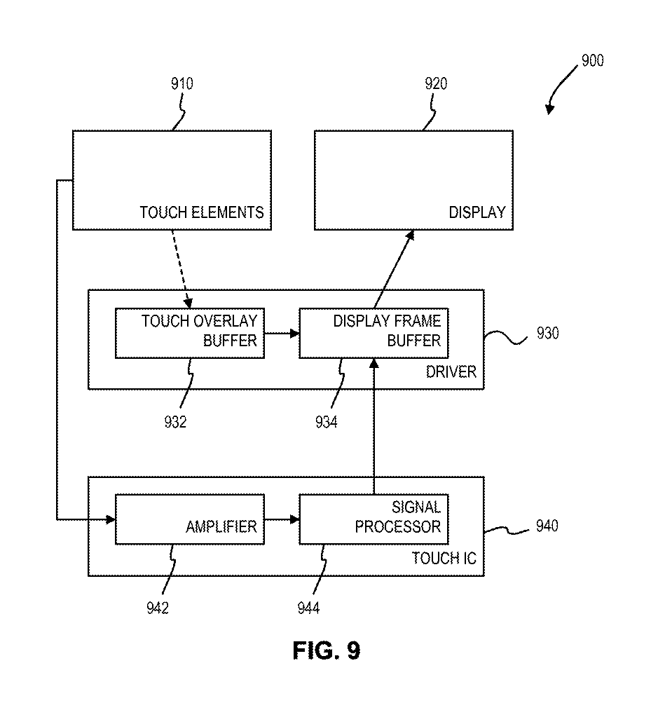

FIG. 9 is a simplified schematic of an example touch event signal flow.

The signal flow 900 occurs between touch sensitive elements of a touch sensor 910, such as pro-cap or pressure sensing elements, a touch sensing integrated circuit 940, a driver 930 and a display 920.

The touch sensing integrated circuit 940 includes an amplifier 942, as described herein, and a signal processor 944, which performs cleanup and touch detection of the raw amplified signal. For example, signal processor 944 can resolve multiple closely spaced touches as a single touch event, or can determine that a sequence of touch events relates to a “swipe” action.

The processed touch signal can be provided to a processor such as display driver 930, and in particular to a display frame buffer 934. The frame buffer 934 can pre-render and store display data before it is actually displayed by the display 920. Prendered data can include “off-screen” data, such as data that is not intended for display in a current view, but which may “scroll” into view in response to a user input, such as a swipe input.

To improve responsiveness to touch events, and to reduce processing latency, raw touch event data may be provided to a touch overlay buffer 932 of the display driver 930 processor. Touch overlay buffer 932 can treat the data from the touch electrode array as a pixelated array of sensors. In effect, touch data can be interpreted as an initial image map, and compressive sensing used to identify the different touch events, including pro-cap and pressure-sensing multi-touch. Pressure levels can be interpreted as levels of grey in the initial image map. This signal processing technique enables fast acquisition and reconstruction of the touch event.

Accordingly, to reduce latency, the raw touch signal from sensor or touch elements 910 is sent directly into the display frame buffer 934 via the touch overlay buffer 932. At the same time, the raw touch signal is provided to the touch sensing integrated circuit 940, where it is amplified by the amplifier 942, and processed and analyzed for location and force parameters by the signal processor 944.

The signal processor 944 can also perform correlated double sampling, for example, to interpret pressure data, carry out signal clean-up, and to generate a processed image map for the multi-touch event. The processed image map can also contain levels of grey representing pressure levels, such that each pixel in the image map has a respective pressure level mapped as a level of grey.

The processed data, including the processed image map, can be provided to the frame buffer, where it can be used to refine the raw touch signal or initial image map through combining or integration. Subsequently, the display frame buffer 934 determines which information should be rendered and pushed to the display 920.

By using the raw, unprocessed touch event data, the display frame buffer 934 can begin pre-rendering display content that is expected to be needed for a display frame based on the touch event (e.g., swipe a certain amount). Once the fully processed touch event data is received, the pre-rendered data can be confirmed and pushed to the display 920, or may be adjusted with incremental cost to render some additional data.

Although described herein as being performed by the signal processor 944, some or all of the described signal procession actions can also be performed by other elements, including a host processor (not shown), or within display driver 930.

It will be appreciated that numerous specific details are set forth in order to provide a thorough understanding of the exemplary embodiments described herein. However, it will be understood by those of ordinary skill in the art that the embodiments described herein may be practiced without these specific details. In other instances, well-known methods, procedures and components have not been described in detail so as not to obscure the embodiments described herein. The scope of the claims should not be limited by the preferred embodiments and examples, but should be given the broadest interpretation consistent with the description as a whole.

We claim:

1. A projected capacitance touchscreen device comprising a pressure sensing assembly, the pressure sensing assembly comprising:
a driving electrode layer;
a sensing electrode layer comprising a plurality of conductive traces, wherein each conductive trace comprises one or more sensing pads;
a piezoelectric layer provided between the driving electrode layer and the sensing electrode layer, wherein the piezoelectric layer acts as a dielectric;
a detection circuit operatively connected to the plurality of conductive traces of the sensing electrode layer, wherein the detection circuit is selectively operable in a first mode and a second mode, wherein for each given conductive trace:
in the first mode the detection circuit is configured to detect a change in capacitance of the given conductive trace of the sensing layer; and
in the second mode the detection circuit is configured to detect a change in electric current resulting from a voltage induced across the piezoelectric layer proximate to the given conductive trace of the sensing layer.

2. The device of claim 1, wherein the driving electrode layer comprises a biasing layer.

3. The device of claim 1, wherein the driving electrode layer comprises a plurality of conductive traces, and wherein each trace comprises one or more driving pads.

4. The device of claim 3, wherein each conductive trace of the driving electrode layer terminates in a respective one of the one or more driving pads.

5. The device of claim 3, wherein each conductive trace of the driving electrode layer comprises a plurality of driving pads.

6. The device of claim 3, wherein each driving pad is formed of an optically transparent conductive material.

7. The device of claim 1, wherein the one or more sensing pads are shaped to maximize fringing fields and a change in capacitance between the sensing electrode layer and the driving electrode layer in response to stimulus.

8. The device of claim 1, wherein the one or more sensing pads have a polygonal shape.

9. The device of claim 1, wherein the driving electrode layer comprises a plurality of conductive traces, wherein each trace comprises one or more driving pads, and wherein the one or more driving pads are aligned with the one or more sensing pads.

10. The device of claim 9, wherein the one or more driving pads are shaped to maximize fringing fields and a change in capacitance between the sensing electrode layer and the driving electrode layer in response to stimulus.

11. The device of claim 1, wherein the one or more driving pads have a polygonal shape.

12. The device of claim 1, wherein each conductive trace of the sensing electrode layer terminates in a respective one of the one or more sensing pads.

13. The device of claim 1, wherein the one or more sensing pads are formed of an optically transparent conductive material.

14. The device of claim 12, wherein the conductive trace further comprises an external portion at a periphery of the device, wherein the external portion is formed of an optically opaque conductive material.

15. The device of claim 1, further comprising a processor, wherein the processor is configured to interpret pressure data from the one or more sensing pads as an image map.

16. The device of claim 15, wherein the pressure data comprises a plurality of pressure levels, and wherein each pixel in the image map has a respective pressure level mapped as a level of grey.

17. The device of claim 15, wherein the pressure data is interpreted using correlated double sampling.

18. The device of claim 17, wherein the pressure data is interpreted using compressive sensing.
